(19) United States
(12) Patent Application Publication
(10) Pub. No.: US 2013/0070418 A1
(43) Pub. Date: Mar. 21, 2013

(54) HEAT DISSIPATION MODULE

(71) Applicants: CHIH-PENG LEE, Tu-Cheng (TW); CHIH-HSUN LIN, Tu-Cheng (TW); CHUN-LIANG CHIANG, Tu-Cheng (TW); LI-HAN CHANG, Tu-Cheng (TW)

(72) Inventors: CHIH-PENG LEE, Tu-Cheng (TW); CHIH-HSUN LIN, Tu-Cheng (TW); CHUN-LIANG CHIANG, Tu-Cheng (TW); LI-HAN CHANG, Tu-Cheng (TW)

(73) Assignee: FOXCONN TECHNOLOGY CO., LTD., Tu-Cheng (TW)

(21) Appl. No.: 13/472,510

(22) Filed: May 16, 2012

(30) Foreign Application Priority Data
Sep. 21, 2011 (TW) 100134033

(51) Int. Cl. H05K 7/20

(52) U.S. Cl. 361/700; 361/720

(57) ABSTRACT

An electronic device includes printed circuit board having an electronic component and a heat dissipation module mounted the printed circuit board. The heat dissipation module includes a base with a heat absorbing plate and two elastic pieces extending from the heat absorbing plate. The heat absorbing plate thermally engages on the electronic component. The elastic pieces are fixed on the printed circuit board. The base is made of one of copper-nickel-silicon alloy, beryllium copper, a titanium copper or phosphor bronze.

### BACKGROUND

1. Technical Field

The present disclosure relates generally to heat dissipation modules, and more particularly to a heat dissipation module for dissipating heat generated by a heat-generating component in an electronic device.

2. Description of Related Art

During operation of an electronic device, a large amount of heat is often produced. The heat must be quickly removed from the electronic device to ensure the normal running of the electronic device. Typically, a heat dissipation module is attached to an outer surface of the electronic device to dissipate the heat generated by the electronic device.

A typical heat dissipation module includes a heat absorbing base, a heat sink, a heat pipe and a mounting plate. Specifically, the heat absorbing base is attached to a heat generating component such as a CPU. The heat pipe connects the heat absorbing base and the heat sink to transfer the heat absorbed by the heat absorbing base to the heat sink. The heat absorbing base is usually made of pure copper for absorbing heat generated from the heat absorbing base. The mounting plate has different function for the heat absorbing base. The mounting plate is usually made of stainless steel with suitable intensity and flexibility for fixing the heat absorbing base onto the heat generating component. However, a thin heat absorbing base made of pure copper has poor intensity. The heat absorbing base is difficult to have a full contact with the heat generating component, thereby influencing heat dissipation capacity of the heat dissipation module.

What is needed, therefore, is a heat dissipation module which can overcome the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an assembled, isometric view of a heat dissipation module in accordance with an embodiment of the disclosure together with an electronic component mounted on a printed circuited board.

FIG. 2 is an inverted view of the heat dissipation module of FIG. 1.

### DETAILED DESCRIPTION

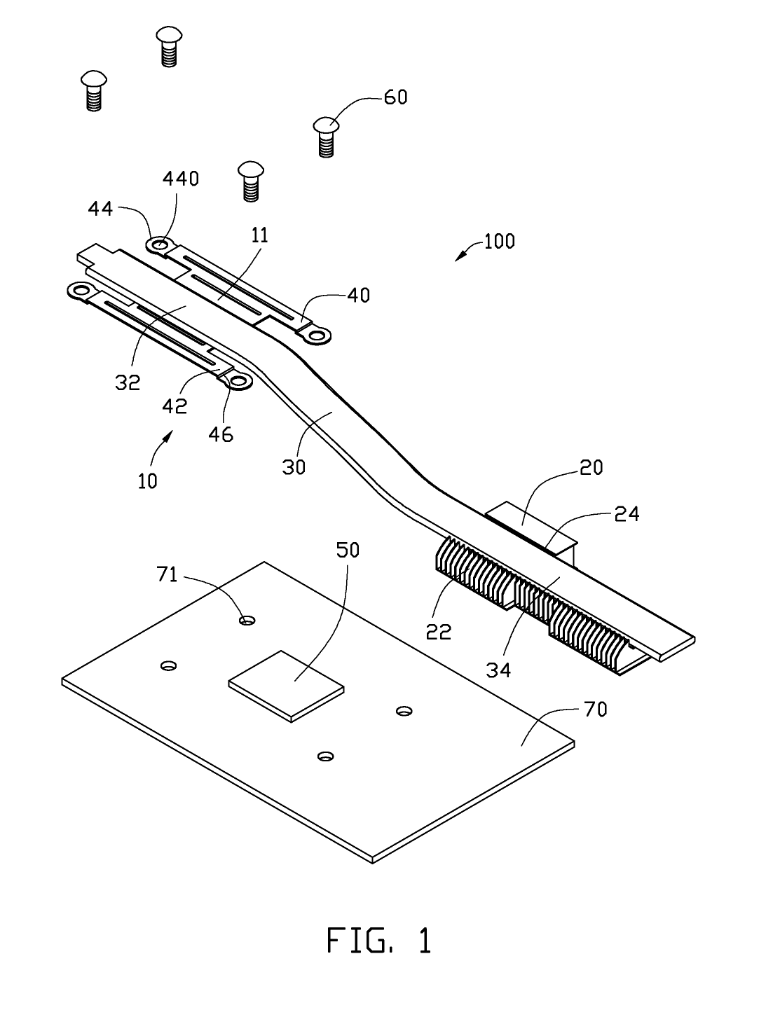

Referring to FIG. 1, an electronic device with a heat dissipation module 100 in accordance with an embodiment of the disclosure is shown. The heat dissipation module 100 is mounted on a printed circuit board 70 to thermally contact the electronic component 50 to dissipate heat generated by the electronic component 50. The printed circuit board 70 defines four mounting holes 71. The heat dissipation module 100 includes a base 10, a heat sink 20 and a heat pipe 30 connecting the base 10 and the heat sink 20. The base 10 is made of one of copper-nickel-silicon alloy, beryllium copper, titanium copper or a phosphor bronze.

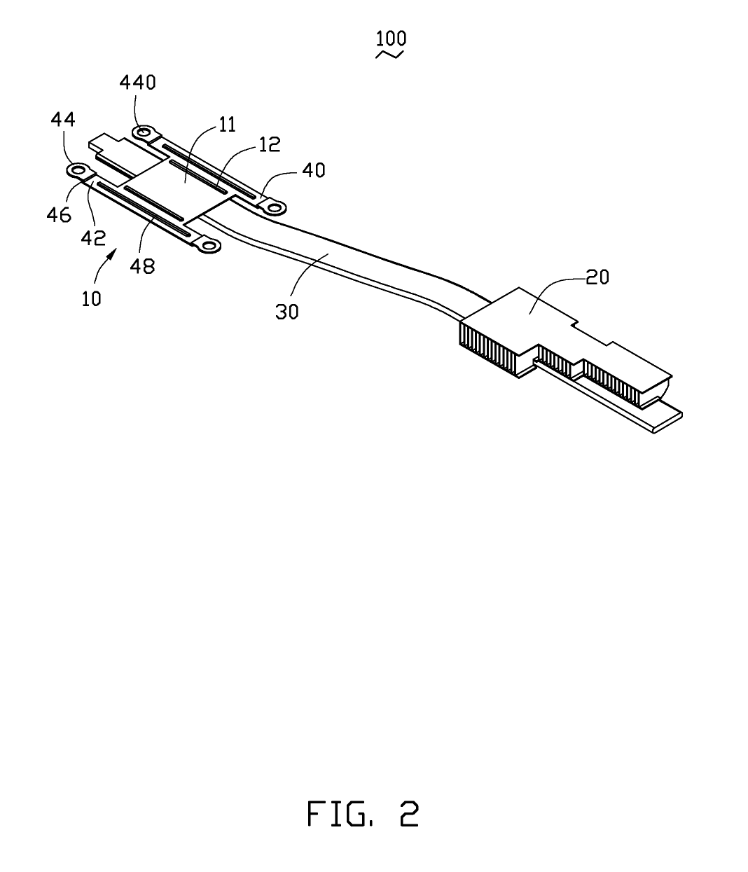

Referring to FIG. 2, the base 10 includes a thin heat absorbing plate 11 and two elastic pieces 40 respectively extending from two sides of the heat absorbing plate 11. The heat absorbing plate 11 and the elastic pieces 40 are integrally made of a metal piece. The heat absorbing plate 11 forms two parallel first ribs 12 downwards from a bottom surface thereof by punching. The first ribs 12 are formed at two lateral portions of the heat absorbing plate 11 and parallel to the elastic pieces 40. Each of the elastic pieces 40 includes an arm portion 42, two mounting portions 44, and two connecting portions 46 respectively connecting two ends of the arm portion 42 and the mounting portions 44. The heat absorbing plate 11 connects a side of each of the arm portions 42. The arm portions 42 are coplanar with the heat absorbing plate 11. The ends of the arm portions 42 extend beyond the heat absorbing plate 11. Each of the arm portions 42 forms a second rib 48 downwards from a bottom surface thereof by punching. The second ribs 48 are parallel to the first ribs 12. Each of the second ribs 48 has a protruding depth as same as that of each of the first ribs 12. The connecting portions 46 are bent downwards from the ends of each of the arm portions 42, and the mounting portions 44 are bent horizontally from bottom ends of corresponding connecting portions 46. The mounting portions 44 are lower than the arm portions 42 and coplanar with bottom ends of the second ribs 48 and the first ribs 12. Each of the mounting portions 44 defines a through hole 440.

The heat sink 20 includes a plurality of fins 22 stacked together and together defining a groove 24. The heat pipe 30 includes an evaporating section 32 attached to a top surface of the base 10 and a condensing section 34 received in the groove 24 of the heat sink 20.

In use, the base 10 is located on the electronic component 50. The first ribs 12 are located at two sides of the electronic component 50 thereby limiting a movement of the base 10 relative to the electronic component 50. A number of screws 60 extend through the through holes 440 of the elastic pieces 40 and engage in the mounting holes 71 of the printed circuit board 70.

Since each of copper-nickel-silicon alloy, beryllium copper, titanium copper or phosphor bronze has thermal conductivity similar to that of pure copper and has suitable intensity and flexibility as same as stainless steel, the base 10 has high heat transferring capacity and elastic distortion to engage the electronic component 50 and the printed circuit board 70. Additionally, the heat absorbing plate 11 and the elastic pieces 40 are integrally made of a metal piece thereby reducing a manufacturing cost thereof. Furthermore, since the bottom ends of the second ribs 48 and the first ribs 12 are parallel to the mounting portions 44, the first ribs 12 and the second ribs 48 abut the printed circuit board 70 to reduce a distortion of the base 10.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
a printed circuit board having an electronic component; and
a heat dissipation module mounted the printed circuit board, the heat dissipation module comprising a base, the base comprising a heat absorbing plate and two elastic pieces extending from the heat absorbing plate, the heat absorbing plate thermally engaging on the electronic component, the elastic pieces being fixed on the printed circuit board, the base being made of one of copper-nickel-silicon alloy, beryllium copper, a titanium copper or phosphor bronze.

2. The electronic device of claim 1, wherein the heat absorbing plate forms two parallel first ribs extending downwards from a bottom surface thereof by punching.

3. The electronic device of claim 2, wherein the first ribs are located at two sides of the electronic component thereby limiting a movement of the base relative to the electronic component.

4. The electronic device of claim 1, wherein the heat absorbing plate and the elastic pieces are integrally made of a metal piece.

5. The electronic device of claim 1, wherein each of the elastic pieces comprises an arm portion connecting the heat absorbing plate, two mounting portions, and two connecting portions respectively connecting the arm portion and the mounting portions.

6. The electronic device of claim 5, wherein the arm portions are coplanar with the heat absorbing plate, the mounting portions being lower than the arm portions.

7. The electronic device of claim 6, wherein each of the arm portions forms a second rib downwards from a bottom surface thereof by punching.

8. The electronic device of claim 7, wherein the mounting portions are lower than the arm portions and coplanar with bottom ends of the second ribs.

9. A heat dissipation module adapted to dissipate heat generated by an electronic component mounted on a printed circuit board, comprising:
a base, the base comprising a heat absorbing plate and two elastic pieces extending from the heat absorbing plate, the heat absorbing plate adapted to thermally engage on the electronic component, the elastic pieces adapted to be fixed on the printed circuit board, the base being made of one of copper-nickel-silicon alloy, beryllium copper, a titanium copper or phosphor bronze;
a heat sink; and
a heat pipe connecting the base and the heat sink.

10. The heat dissipation module of claim 9, wherein the heat absorbing plate and the elastic pieces of the base are integrally made of a metal piece.

11. The heat dissipation module of claim 9, wherein the heat absorbing plate of the base forms two parallel first ribs extending downwards from a bottom surface thereof by punching for abutting the printed circuit board.

12. The heat dissipation module of claim 11, wherein the first ribs are located at two sides of the electronic component thereby limiting a movement of the base relative to the electronic component.

13. The heat dissipation module of claim 11, wherein each of the elastic pieces forms a second rib downwards from a bottom surface thereof by punching for abutting the printed circuit board.

14. The heat dissipation module of claim 11, wherein the second ribs are parallel to the first ribs.

15. The heat dissipation module of claim 11, wherein the heat sink comprises a plurality of fins and defines a groove, the heat pipe comprising an evaporating section attached to a top surface of the base and a condensing section received in the groove of the heat sink.
